(19) United States
(12) Patent Application Publication
(10) Pub. No.: US 2009/0120787 A1
(43) Pub. Date: May 14, 2009

(54) METHOD OF MANUFACTURING SEMICONDUCTOR DEVICE

(75) Inventors: Yoshihiro OKAMURA, Susono-shi (JP); Satoru Toyoda, Susono-shi (JP); Michio Ishikawa, Susono-shi (JP)

Correspondence Address: KRATZ, QUINTOS & HANSON, LLP, 1420 K Street, N.W., Suite 400, WASHINGTON, DC, 20005, US

(73) Assignee: ULVAC, INC., Chigasaki-shi (JP)

(21) Appl. No.: 12/352,011

(22) Filed: Jan. 12, 2009

Related U.S. Application Data
(63) Continuation of application No. PCT/JP2007/063891, filed on Jul. 12, 2007.

(30) Foreign Application Priority Data
Jul. 14, 2006 (JP) 2006-193879

(51) Int. Cl. C23C 14/34

(52) U.S. Cl. 204/192.25

(57) ABSTRACT

A barrier film of a semiconductor device is formed. The present invention forms a middle layer having copper as a main component and including a predetermined quantity of diffusible metal with the addition of a reaction gas, by sputtering an alloy target having copper as a main component with the addition of a diffusible metal, while supplying a reaction gas including oxygen or nitrogen. Since contents of the diffusible metal are accurately controlled when heating the middle layer, the barrier film is certainly formed. Additionally, the reaction gas is added to the middle layer so that the reactivity of the diffusible metal becomes high; and accordingly, it is possible to form the barrier film at a heating temperature lower than the conventional art.

This is a Continuation of International Application No. PCT/JP2007/063891 filed Jul. 12, 2007, which claims priority to Japan Patent Application No. 2006-193879, filed on Jul. 14, 2006. The entire disclosures of the prior applications are hereby incorporated by reference herein in their entireties.

### BACKGROUND

The present invention generally relates to a method of forming a film, and more particularly to a method of forming a film used for a process of manufacturing a semiconductor device.

Conventionally, as for wiring materials of a semiconductor element, copper is widely used. Copper has an advantage in that it has a resistance value that is low as compared to other wiring materials such as Al. However, since diffusion speed is fast in a silicon oxide film or silicon, when copper is used as the wiring material, it is necessary to form a barrier film for preventing diffusion of copper between the wiring and the silicon oxide layer.

It is known that, when a copper thin film is heated after a copper target and a Mn target are sputtered in the same vacuum chamber to form the copper thin film having copper as a main component with Mn added on a substrate surface, a thin film of manganese oxide is deposited on an interface between the thin film and the substrate, and the thin film functions as a barrier film (for instance, refer to non-patent document 1 below).

However, in the method described above, since two kinds of targets are sputtered in the same vacuum chamber, a device configuration should be special, so that it is not possible to use conventional film forming devices.

Additionally, in order to precisely control an additive quantity of Mn in the copper thin film, it is necessary to control film forming speeds of the respective targets one by one; however, since surface condition of the targets varies in the sputtering, it is difficult to maintain the film forming speed constant.

When the additive quantity of Mn is not precisely controlled, manganese oxide is not deposited even when the copper thin film is heated; and additionally, even when the additive quantity of Mn can be controlled, it is necessary to heat the substrate at high temperature in order to deposit manganese oxide.

See, Non-Patent Document “Applied Physics Letters”, (U.S.A.) 2005, 87, 041911.

### SUMMARY OF THE INVENTION

The present invention is achieved to solve the above described problems, and its object is to provide a simple method of forming a film to thereby surely form a barrier film.

In order to solve the above described problems, the present invention provides a method of manufacturing a semiconductor device which forms a thin film containing copper as a main component by sputtering on a sidewall of a hole of a processing object having a substrate and a first insulating film disposed on a surface of the substrate and with the hole formed therein, the method having a middle layer forming process including the steps of: supplying a reaction gas that reacts with a diffusible metal to form an oxide or nitride of the diffusible metal, and a sputtering gas into a vacuum chamber in which a target and the processing object are disposed, the target being added with at least one kind of the diffusible metal selected from a diffusible metal group consisting of a transition metal, Al and Mg; and sputtering the target by applying a voltage thereto to form a middle layer with copper as a main component and also including the diffusible metal and the reaction gas.

The present invention is directed to a method of manufacturing a semiconductor device having an etching process including the steps of: after the middle layer forming process, applying a voltage lower than the voltage applied in the middle layer forming process to the target; and applying a high frequency voltage to a substrate holder holding the processing object.

The present invention is directed to a method of manufacturing a semiconductor device having a heating process including the step of, after the etching process, heating the middle layer to form a barrier film including a nitride or oxide of the diffusible metal on a surface of the sidewall of the hole, and an underlayer containing copper as a main component on a surface of the barrier film.

The present invention is directed to a method of manufacturing a semiconductor device having a process including the step of; after the etching process, depositing a metal layer on a bottom of the hole and on the sidewall of the hole with a surface of a metal wiring positioned on the bottom of the hole.

The present invention is directed to a method of manufacturing a semiconductor device, wherein a second insulating film having a trench with the first insulating film exposed is disposed on the first insulating film; the hole is disposed on a bottom of the trench; and the middle layer forming process also forms a middle layer on a sidewall of the trench and a bottom of the trench.

The present invention is directed to a method of manufacturing a semiconductor device, wherein the etching process leaves the middle layer that grows on the bottom of the trench.

A “main component” in the present invention means that materials of the main component of 50 at. % (atomic %) or more are contained. That is, the middle layer containing copper as a main component is a middle layer including copper of 50 at. % or more, and a target containing copper as a main component is a target including copper of 50 at. % or more.

Meanwhile, the high frequency voltage applied to the substrate holder in the middle layer forming process and the voltage applied to the target in the etching process respectively include the case of zero volt.

The target used for the present application is an alloy target including copper as a main component with the addition of diffusible metal. Since the composition of the middle layer growing on a surface of the processing object agrees with the composition of the alloy target, it is possible to accurately control the additive quantity of the diffusible metal within the middle layer.

Although the middle layer can also be formed in the case where, without using the alloy target, a copper target (pure copper target including no diffusible metal) and a diffusible metal target are sputtered, it is hard to control additive quantity of the diffucible metal accurately, as described above.

Moreover, since the target of the diffusible metal has weak mechanical strength as compared to the alloy target, particles occur more than in the alloy target during the sputtering. Additionally, it is necessary to adjust an exchanging timing of the target to the exchanging timing of either a copper target or a diffusible target. As such, it is necessary to exchange the target frequently as compared to the case of the alloy target.

By adding reactive gasses into a middle layer, reactivity of a diffusible metal becomes high; and it is possible to form a barrier film at lower temperature than the conventional art. Since it is possible to accurately control the additive quantity of the diffusible metal of the middle layer, it is possible to surely form the barrier film. Since the barrier film is formed certainly, copper of an underlayer or a metal wiring is not diffused, so that reliability of the semiconductor device becomes high. The barrier film formed by the present application not only has an excellent barrier property to copper, but also makes the underlayer tightly adhere to a processing object; and therefore, the metal wiring is made less likely to exfoliate from the processing object.

### BRIEF DESCRIPTION OF THE DRAWINGS

FIG. 1 is a cross sectional view illustrating one example of a film forming device used for the present invention;

FIGS. 2(a) to 2(d) are cross sectional views illustrating a first half of a manufacturing process of the semiconductor device;

FIGS. 3(a) and 3(b) are cross sectional views illustrating a last half of a manufacturing process of the semiconductor device;

FIG. 4 is a cross sectional view illustrating a heating device;

FIG. 5 is a perspective view of the semiconductor device; and

FIG. 6 is a graph showing the relationships between oxygen flow rate, and either a specific resistance value changing rate or in-plane distribution of a sheet resistance value.

### DETAILED DESCRIPTION OF THE EMBODIMENTS

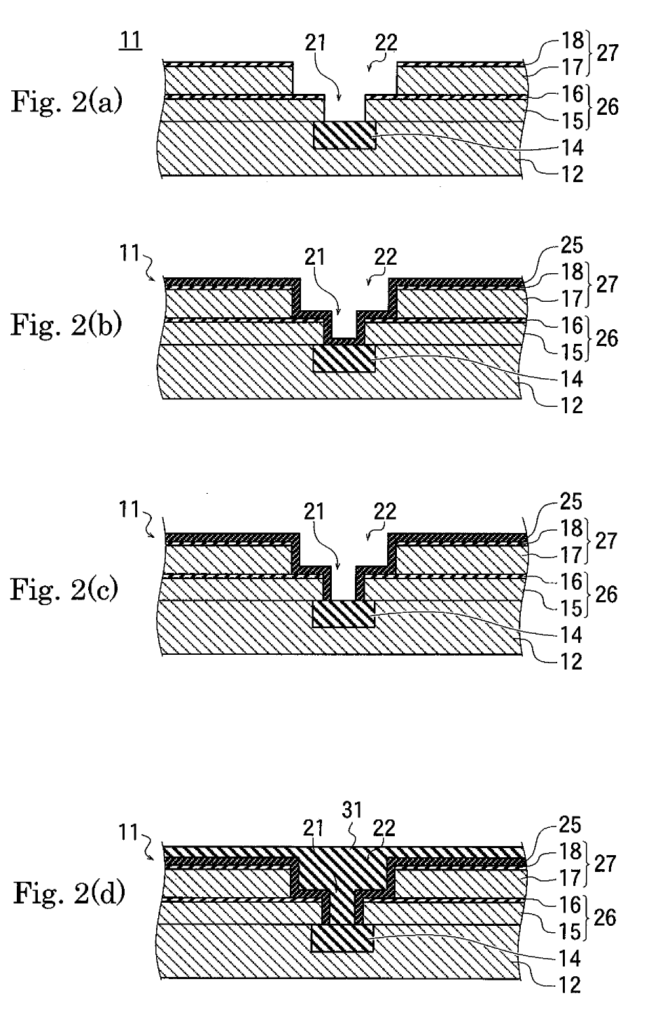

A reference numeral 11 of FIG. 2(a) shows a processing object used for the present invention. The processing object 11 has a substrate 12. A trench is formed on a surface of the substrate 12, and a first metal wiring 14 is disposed in the trench.

A lower insulating layer 15 is disposed on a surface of the substrate 12 where the first metal wiring 14 is disposed; a first protection film 16 is disposed on a surface of the lower insulating layer 15; and a first insulating film 26 is formed of the lower insulating layer 15 and the first protection film 16.

An upper insulating layer 17 is disposed on a surface of the first protection film 16; a second protection film 18 is disposed on a surface of the upper insulating layer 17; and a second insulating film 27 is formed of the upper insulating layer 17 and the second protection film 18.

Through-holes penetrating the first and second insulating films 26, 27 are formed just above the position of the first metal wiring 14 on the first and second insulating films 26, 27; the second insulating film 27 is subjected to a patterning; and a trench 22 passing through a position crossing the through-hole is formed.

Reference numeral 21 shows a hole being a part of the through-hole penetrating the first insulating film 26, and as described above, the trench 22 intersects the through-hole; therefore, an opening of the hole 21 is exposed on a bottom of the trench 22.

The first protection film 16 is used as an etching stopper of the upper insulating layer 17 when forming the trench 22; and therefore, the first protection film 16 is exposed on the parts other than the hole 21 of a bottom of the trench 22.

Next, the following is a description of a manufacturing method of the present invention directed to the manufacturing of the semiconductor device using the processing object 11.

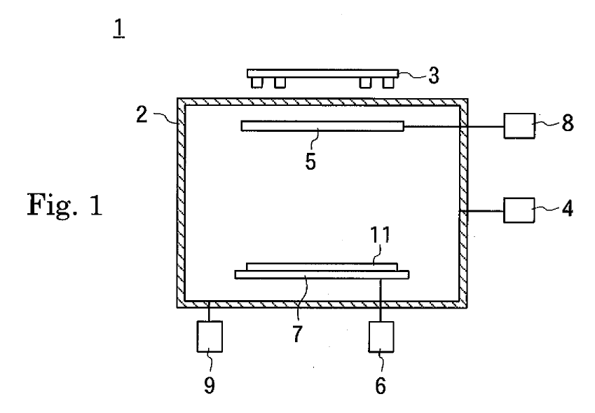

Reference numeral 1 of FIG. 1 shows one example of a film forming device used for the present invention.

The film forming device 1 has a vacuum chamber 2, a substrate holder 7 and a target 5, both the substrate holder 7 and the target 5 being disposed in the vacuum chamber 2.

A vacuum evacuation system 9 and a gas supply system 4 are connected to the vacuum chamber 2. The inside of the vacuum chamber 2 is vacuum-evacuated, while introducing sputtering gasses and reaction gasses including nitrogen or oxygen in their chemical structure (for instance, when the reaction gas is oxygen, flow rate is 0.1 sccm or more and 5 sccm or less) from the gas supply system 4 by performing the vacuum evacuation. Therefore, a film forming atmosphere (for instance, “total pressure” is 10⁻⁴ Pa or more and 10⁻¹ Pa or less) lower than an atmospheric pressure inside the vacuum chamber 2 is formed.

The above described processing object 11 is kept on a substrate holder 7 under the condition that the surface on which the trench 22 is formed is directed to the target 5.

A sputtering power source 8 and a bias power source 6 are disposed outside the vacuum chamber 2; and the target 5 is connected to the sputtering power source 8 and the substrate holder 7 is connected to the bias power source 6.

A magnetic field formation device 3 is disposed outside the vacuum chamber 2; and when the vacuum chamber 2 is set to a ground potential, a negative voltage is applied to the target 5, while the film forming atmosphere inside the vacuum chamber 2 is maintained, and then the target 5 is magnetron-sputtered.

The target 5 is an alloy target including copper as a main component, with manganese added by predetermined quantity (for instance, exceeding 2 at. %); and when the target 5 is magnetron- sputtered, sputtered particles including copper as a main component and made of alloy materials with the addition of manganese are discharged.

The discharged sputtered particles and the reaction gas are incident on a surface of the processing object 11 on which the trench 22 is formed, so that a thin film in which the reaction gas is included in the above-mentioned alloy material grows on the surface.

At this time, a high frequency voltage (including 0V) is applied to the substrate holder 7; plasmas with quantity in accordance with magnitude of the high frequency voltage are made incident into the surface of the processing object 11 on which the trench 22 is formed; and the thin film growing on the surface is etched.

The magnitudes of the negative voltage and the high frequency voltage are set to values such that a film thickness growing speed (sputtering speed) of the thin film (assuming that the thin film is not etched) becomes larger than a film thickness decreasing speed (etching speed)of the thin film (assuming that the thin film does not grow but is subjected to only the etching). Accordingly, as shown in FIG. 2(b), the thin film 25 grows on a sidewall and a bottom of the trench 22, a sidewall and a bottom of the hole 21, and a surface of the second insulating film 27 (a middle layer forming process).

The application of the negative voltage to the target 5 and the application of the high frequency voltage to the substrate holder 7 are continued for a predetermined time period. When the thin film 25 grows to a predetermined film thickness, the voltages applied to the target 5 and the substrate holder 7 are adjusted such that etching speed of the thin film becomes large, while the introduction of the sputtering gas and the reaction gas, and vacuum evacuation are continued. For instance, the sputtering speed is decreased by reducing the discharge amount of sputtered particles, while making the voltage applied to the target 5 smaller than a voltage before the thin film grows to a predetermined film thickness. Alternatively, an etching speed may be increased by increasing an incidence quantity of plasma while making the voltage applied to the substrate holder 7 larger than the voltage before the thin film grows to a predetermined film thickness.

Since plasma is made incident nearly vertically on the bottom of the hole 21, the thin film 25 on the bottom of the hole 21 is etched; however, since plasma is not made incident vertically on a side wall of the hole 21 and a side wall of the trench 22, the thin film 25 remains.

At this time, the high frequency voltage applied to the substrate holder 7, the negative voltage applied to the target 5, and the flow rate of the sputtering gas are set such that the thin film 25 remains on the bottom of the trench 22 and a surface of the second insulating film 27; application of the high frequency voltage and application of the negative voltage are continued during a predetermined period of time; and subsequently, application of the high frequency voltage and application of the negative voltage are stopped respectively at the stage when the first metal wiring 14 is exposed after the middle layer 25 is removed from the bottom of the hole 21 (etching process).

FIG. 2(c) shows a state after completing the etching process. Although the surface of the first metal wiring 14 is exposed on the bottom of the hole 21, the middle layer 25 remains on a sidewall of the hole 21, a bottom and a sidewall of the trench 22, and a surface of the second insulating film 27.

The middle layer 25 on the sidewall of the hole 21, the middle layer 25 on the bottom and the sidewall of the trench 22, and the middle layer 25 on the surface of the second insulating film 27 are continued. Although the middle layer 25 is removed from the bottom of the hole 21, since the middle layer 25 on the sidewall of the hole 21 comes into contact with a surface of the first metal wiring 14 at the bottom of the hole 21, and the middle layer 25 contains copper as a main component, as described above, the middle layer 25 on the sidewall of the hole 21, the middle layer 25 on the bottom and the sidewall of the trench 22, the middle layer 25 on the surface of the second insulating film 27 and the respective first metal wirings 14 are electrically connected.

When immersing the processing object 11 into an electrolytic plating solution at this stage and electrifying the middle layer 25, a metal layer 31 grows on a part located at the bottom of the hole 21 on the surface of the first metal wiring 14 and the surface of the middle layer 25; and the inside the trench 22 and the inside the hole 31 are filled with the metal layer. FIG. 2(d) shows the processing object 11 in a state in which the metal layer 31 is formed.

Reference numeral 35 of FIG. 4 shows a heating device, and the heating device 35 has a heating room 36 and a vacuum evacuation system 37 connected to the heating room 36. The vacuum atmosphere is formed inside the heating room 36 while starting the vacuum evacuation system 37, and the processing object 11 with the metal layer 31 formed thereon is carried in the heating room 36 while maintaining the vacuum atmosphere.

A heater 38 is disposed inside the heating room 36; and the heater 38 is electrified. In order to prevent the metal layer 31 from being oxidized, the metal layer 31 is subjected to annealing processing while heating the processing object 11 at a higher temperature (for instance, at 350° C. for two hours) than the temperature increased at the time of the above described middle layer forming process and the etching process, with the vacuum atmosphere maintained.

Diffusion speed of manganese is fast within copper. Consequently, when the middle layer 25 increases temperature at the time of the annealing process, manganese included in the middle layer 25 diffuses and reaches the sidewall of the hole 21, the sidewall and the bottom of the trench 22, and the surface of the second insulating film 27, respectively.

The lower insulating layer 15 and the first protection film 16 are positioned at the sidewall of the hole 21; and the upper insulating layer 17 and the second protection film 18 are positioned at the sidewall of the trench 22. In this embodiment, the first and the second protection films 16, 18 are made of nitride (such as SiN); and the lower insulating layer 15 and the upper insulating layer 17 are made of oxide (such as SiO₂).

The reactivity of manganese to nitrogen and oxygen is higher than that of copper; and, the reactivity has been further heightened by the addition of the above-described reaction gas to the middle layer 25.

Manganese nitride is deposited, while manganese reacts with nitride contained in the first and the second protection films 16, 18 at an interface between the first protection film 16 and the middle layer 25 and at an interface between the second protection film 18 and the middle layer 25. Manganese oxide is deposited, while manganese reacts with oxide contained in the lower insulating film 15 and the upper insulating film 17 at an interface between the lower insulating film 15 and the middle layer 25 and an interface between the upper insulating film 17 and the middle layer 25.

At this stage, when the reaction gas includes nitrogen, manganese nitride, which is a reaction between nitrogen of the reaction gas, and manganese is deposited at the interfaces; and when the reaction gas includes oxygen, manganese oxide, which is a reaction between oxygen of the reaction gas and manganese, is deposited at the interfaces.

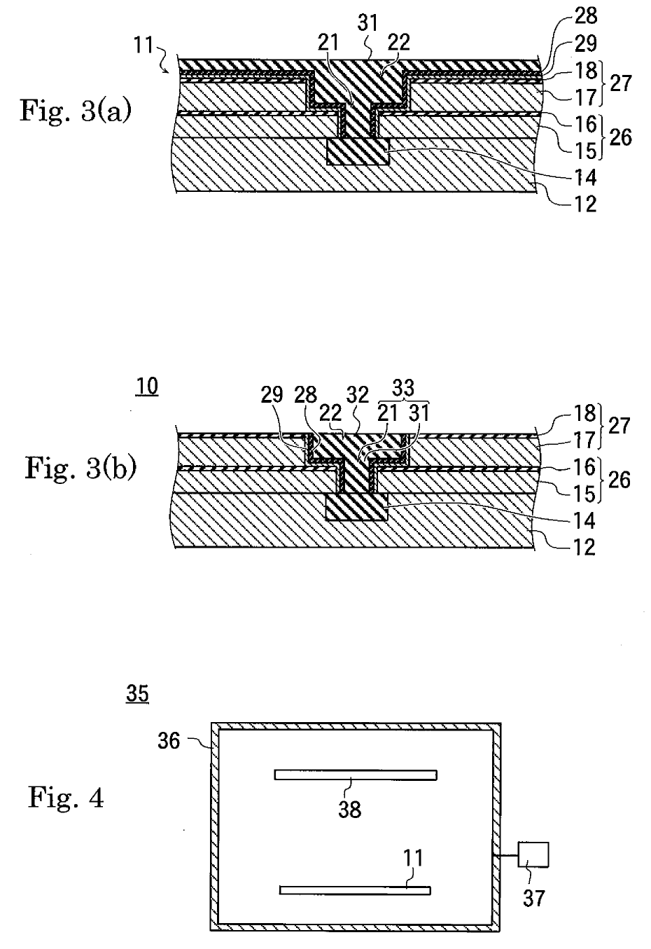

Therefore, a barrier film 29 is formed at the interface between the first protection film 16 and the middle layer 25, and at the interface between the second protection film 18 and the middle layer 25, while manganese nitride, or both manganese nitride and manganese oxide are deposited; and a barrier film 29 is formed at the interface between the lower insulating layer 15 and the middle layer 25, and the interface between the upper insulating layer 17 and the middle layer 25, while manganese oxide, or both manganese oxide and manganese nitride are deposited (FIG. 3(a)).

When the barrier film 29 is formed, parts of copper as a main component of the middle layer 25, Mn, and the reaction gas remain on a surface of the barrier film 29, and the remaining middle layer 25 results in an underlayer 28.

Like the middle layer 25, the underlayer 28 contains copper as a main component, although copper is easily diffused into silicon oxide or silicon. However, since manganese oxide and manganese nitride naturally shield the diffusion of copper, copper is shielded by the barrier film 29, so that copper does not invade both the lower insulating layer 15 and the upper insulating layer 17.

Next, the grinding of the surface of the processing object 11 on which the metal layer 31 is formed occurs so as to remove the metal layer 31 until a surface of the second insulating film 27 is exposed by, for instance, the CMP (Chemical Mechanical Polishing) method. The metal layer 31 between the trenches 22 is removed, and the metal layers 31 that fill the trenches 22 are separated from each other so that a second metal wiring 32 is formed (FIG. 3(b)).

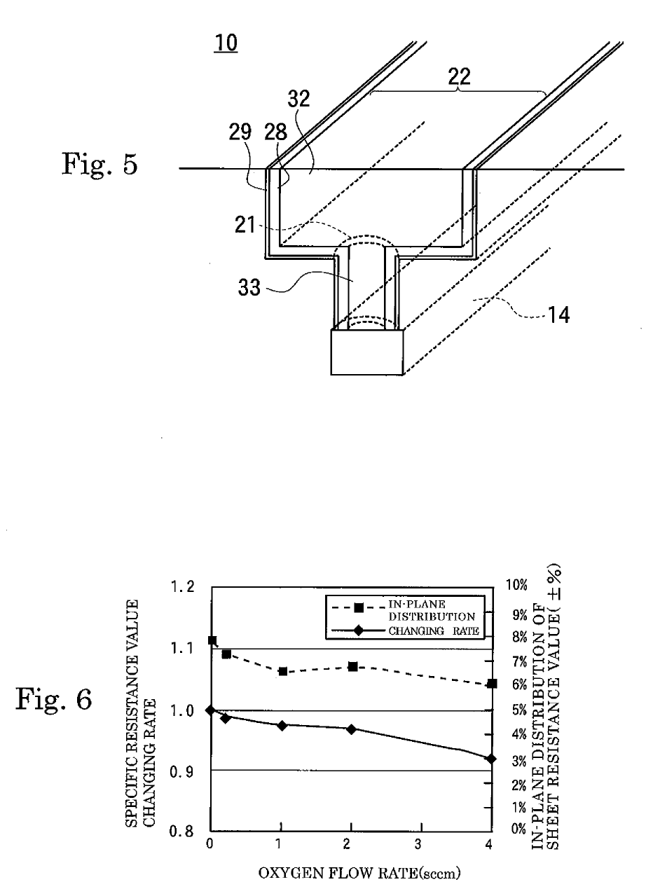

Reference numeral 10 of FIG. 3(b) and FIG. 5 shows a semiconductor device with the second metal wiring 32 formed. A state of the inside of the hole 21 filled with the metal layer 31 remains; and a contact hole 33 connecting the first and the second metal wirings 14, 32 to each other with the hole 21 filled with the metal layer 31 is formed.

As described above, since the middle layer 25 is not formed on the bottom of the hole 21, the barrier layer is not formed between the contact hole 33 and the first metal wiring 14, and electric resistance between the first and the second metal wirings 14, 32 is low.

The barrier film 29, which includes either or both manganese oxide and manganese nitride, has high adhesiveness to both silicon compound (such as, SiO₂ or SiN), and metallic materials (such as, copper or aluminum).

Since the barrier film 29 is positioned between the underlayer 28 containing copper as a main component and the first and the second insulating films 26, 27 including SiO₂ or SiN, the underlayer 28 is strongly fixed to the bottom and the sidewall of the trench 22, and an inner wall of the hole 21. Since the underlayer 28 is high in adhesiveness to the second metal wiring 32, the second metal wiring 32 is fixed inside the trench 22 by the underlayer 28 and the barrier film 29; thus, it will be difficult for the second metal wiring 32 to fall from the semiconductor device 10.

The above description is made for the case where etching process is performed after the middle layer forming process, and the metal wiring 14 is exposed on the bottom of the hole 21; however, the present invention is not limited to this. The middle layer 25 may remain on the bottom of the hole 21 as long as the resistance between the first and the second metal wirings 14, 32 is sufficiently low.

The above description is made for the case where the underlayer structure is made one-layered; however, the present invention is not limited to this. For instance, separately from the alloy target 5, a high purity copper target is disposed inside the vacuum chamber 2; and after completing the etching process, the underlayer may be laminated into two layers or more, while the copper thin film is laminated by sputtering the high purity copper target.

In this case, even though the middle layer 25 is removed from the bottom of the trench 22 by the etching process and the middle layer 25 is divided, since the divided middle layer 25 is electrically connected by the copper thin film growing on the bottom of the trench 22, it is possible to form the metal layer 31 filling the trench 22 by a plating method. However, when a film of SiO₂ is exposed on the bottom of the trench 22, copper is diffused from the copper thin film; and accordingly, it is desirable for a film (for instance, SiN film) having shielding performance to copper to be positioned on a surface of the first insulating film 26.

To function as the etching stopper when patterning the upper insulating layer 17, and etching speed is slower than the upper insulating film 17, a constituent material of the first protection film 16 is not limited to SiN.

A heating process forming a barrier film and an underlayer while heating the middle layer 25 maybe performed before forming the metal layer 31; however, if the heating process is performed after forming the metal layer 31, heating of the middle layer 25 and annealing processing of the metal layer 31 are performed simultaneously, so that not only is manufacturing time reduced, but also surplus thermal damage to the processing object 11 is avoided.

Additionally, if nitride or oxide of a diffusible metal is deposited at the interface between the processing object 11 and the middle layer 25 at a temperature heated up when sputtering the alloy target, it is not necessary to specifically provide a process for heating the middle layer 25.

The above describes the case where the Mn-added alloy target (target 5) is used as the diffusible metal; however, the present invention is not limited to this.

If the diffusible metal having fast diffusion speed in copper, and also reacts with nitrogen or oxygen, various kinds of transition metals (such as, Ti, Ta, Mo, W, V) or nontransition metals (such as, Mg and Al), in addition to Mn, can be added to the target 5 as the diffusible metals.

These transition metals may be added to the alloy target 5 individually, or two kinds or more may be added.

Although an additive quantity of the diffusible metal in the alloy target 5 is not particularly limited, the additive quantity is, for instance, 1 at. % or more and 40 at. % or less.

The reaction gas is not particularly limited, if including oxygen or nitrogen in the chemical structure and oxide or nitride is generated by being reacted with the diffusible metal, H₂O, O₃, CO, N₂, or NH₃ can, for instance, be used. These reaction gasses may be used one kind individually, although two kinds or more may be used.

Sputtering gasses are not limited particularly. It is possible to use at least one kind among the inert gasses selected from a group consisting of Ar gas, Ne gas, Xe gas and Kr gas.

The constituent material of the lower insulating layer 15 and the upper insulating layer 17 is not limited to the case of being formed of SiO₂, and it is possible to use one including either one kind or more selected from a group consisting of SiO₂, SiN, SiOC, and SiC.

Constituent materials of the first and the second metal wirings 14, 32 are not particularly limited and various conductive materials (such as, Cu, Al) can be used. However, since the underlayer 28 contains copper as a main component, when considering adhesiveness to the underlayer 28, it is desirable that the constituent material of the second metal wiring 32 contains copper as a main component. When the constituent material of the second metal wiring 32 contains copper as a main component, with respect to electric characteristic, it is desirable that the constituent material of the first metal wiring 14 contains copper as a main component.

The above describes the case of the processing object 11 in which the second insulating film 27 is disposed on the first insulating film 26, and the hole 21 is positioned on the bottom of the trench 22 of the second insulating film 27; however, the present invention is not limited to this.

Also included in the present invention is, for instance, the case where the second insulating film 27 is not formed, and the semiconductor device is manufactured using the processing object 11 in which the surface of the first insulating film 26 is exposed.

Although the flow rate of the reaction gas introduced into the vacuum chamber 2 at the time of the middle layer forming process and the etching process are not particularly limited, for instance, the flow rate may be 0.1 sccm or more and 5 sccm or less and at this time, the pressure inside the vacuum chamber 2 may be, for instance, 10⁻⁴ Pa or more and 10⁻¹ Pa or less.

The above describes the case in which, in both the middle layer forming process and the etching process, the application voltage to the target 5 is decreased in two stages; however, the present invention is not limited to this. The application voltage to the target 5 may be decreased in a stepwise fashion of three times or more. The application voltage may be decreased gradually and continuously, not in a stepwise fashion. Similarly, the high frequency voltage may be increased in a stepwise fashion of three times or more, and the high frequency voltage may be increased gradually and continuously not in a stepwise fashion.

### EXAMPLE

### <Adhesiveness Test>

The middle layer 25 is formed by performing the middle layer forming process and the etching process while respectively varying partial pressure of the reaction gas (O₂, oxygen) within a film forming atmosphere and Mn additive quantity of the target 5. Thereafter, the semiconductor device 10 is manufactured in the above described process. Here, the conditions of the annealing are such that pressure of the vacuum atmosphere is 6×10⁻⁶ Pa, heating temperature is 350° C., and heating time is one hour.

Lattice-shaped flaws are formed on a surface of a formation side on which the second metal wiring 32 of the obtained semiconductor device 10 is formed. Presence of peeling of the second metal wiring 32 is observed after an adhesive tape is adhered on a part on which flaws of the surface of the semiconductor element 10 are formed and then the adhesive tape is peeled. Results together with oxygen partial pressures and Mn additive quantities of the target 5 are shown below in Table 1.

TABLE 1
Table 1: Adhesiveness Test

| | | | 10⁻³ Pa or more and |
|---|---|---|---|
| O₂ Partial Pressure | 0 Pa | Less than 10⁻³ Pa | 10⁻² Pa or less |
| Mn: 2 at. % | X | X | ◯ |
| Mn: 7 at. % | X | X | X |

In the above Table 1, a symbol “◯” shows the case where peelings of the second metal wiring 32 are not observed, while a symbol “x” shows the case where the peeling of the second metal wiring 32 is observed.

As is clear from the above Table 1, when an additive quantity of Mn is 2 at. % or less and partial pressure of the oxygen gas is less than 10⁻³ Pa, the adhesiveness was bad. From the result of the experiment, if the additive quantity of Mn exceeds 2 at. %, and the oxygen gas partial pressure is 10⁻³ Pa or more, it is confirmed that the adhesiveness of the second metal wiring 32 becomes high.

### <Resistance Value>

The middle layer 25 is formed by performing the middle layer forming process and the etching process using the target with 7 at. % of Mn additive quantity while varying the flow rates of the oxygen gas being the reaction gas; thereafter, the semiconductor device 10 is manufactured in the above described process.

Specific resistances and variations of the resistance values of the first and the second metal wirings 14, 32 of the respective semiconductor devices 10 are measured; and their measured results are shown in a graph of FIG. 6.

As is clear from FIG. 6, even when increasing an oxygen flow rate, an increase of specific resistance so as to bring about the wiring resistance increase of the first and the second metal wirings 14, 32 is not found. From this result, even when introducing oxygen during the middle layer forming process and the etching process, it is found that the electric characteristics of the metal wiring do not deteriorate.

What is claimed is:

1. A method of manufacturing a semiconductor device which forms a thin film containing copper as a main component by sputtering on a sidewall of a hole of a processing object having a substrate and a first insulating film disposed on a surface of the substrate and with the hole formed therein, the method comprising a middle layer forming process including the steps of:
supplying a reaction gas that reacts with a diffusible metal to form an oxide or nitride of the diffusible metal, and a sputtering gas into a vacuum chamber in which a target and the processing object are disposed, the target being added with at least one kind of the diffusible metal selected from a diffusible metal group consisting of a transition metal, Al and Mg; and
sputtering the target by applying a voltage thereto to form a middle layer with copper as a main component and also including the diffusible metal and the reaction gas.

2. The method of manufacturing a semiconductor device according to claim 1, further comprising an etching process including the steps of: after the middle layer forming process,
applying a voltage lower than the voltage applied in the middle layer forming process to the target; and
applying a high frequency voltage to a substrate holder holding the processing object.

3. The method of manufacturing a semiconductor device according to claim 2, further comprising a heating process including the step of, after the etching process,
heating the middle layer to form a barrier film including a nitride or oxide of the diffusible metal on a surface of the sidewall of the hole, and an underlayer containing copper as a main component on a surface of the barrier film.

4. The method of manufacturing a semiconductor device according to claim 3, further comprising a process including the step of; after the etching process,
depositing a metal layer on a bottom of the hole and on the sidewall of the hole with a surface of a metal wiring positioned on the bottom of the hole.

5. The method of manufacturing a semiconductor device according to claim 1,
wherein a second insulating film having a trench with the first insulating film exposed is disposed on the first insulating film,
wherein the hole is disposed on a bottom of the trench, and
wherein the middle layer forming process also forms a middle layer on a sidewall of the trench and a bottom of the trench.

6. The method of manufacturing a semiconductor device according to claim 5, wherein
the etching process leaves the middle layer that grows on the bottom of the trench.
